(19) United States
(12) Patent Application Publication
(10) Pub. No.: US 2015/0136210 A1
(43) Pub. Date: May 21, 2015

(54) SILICON-BASED SOLAR CELLS WITH IMPROVED RESISTANCE TO LIGHT-INDUCED DEGRADATION

(71) Applicant: TEL SOLAR AG, Trübbach (CH)

(72) Inventors: Xavier Multone, Monthey (CH); Daniel Borrello, Cortaillod (CH); Stefano Benagli, Neuchatel (CH); Johannes Meier, Corcelles (CH); Ulrich Kroll, Corcelles (CH); Marian Fecioru-Morariu, Chur (CH)

(21) Appl. No.: 14/400,095

(22) PCT Filed: May 10, 2013
(86) PCT No.: PCT/EP2013/001393

§ 371 Date: Nov. 10, 2014

Related U.S. Application Data
(60) Provisional application No. 61/645,121, filed on May 10, 2012.

(51) Int. Cl. H01L 31/0232; H01L 31/054; H01L 31/075; H01L 31/0376; H01L 31/20

(52) U.S. Cl. CPC H01L 31/02327; H01L 31/03765; H01L 31/204; H01L 31/075; H01L 31/0547
USPC 136/255; 438/69; 438/72

(57) ABSTRACT

Solar devices with high resistance to light-induced degradation are described. A wide optical bandgap interface layer positioned between a p-doped semiconductor layer and an intrinsic semiconductor layer is made resistant to light-induced degradation through treatment with a hydrogen-containing plasma. In one embodiment, a p-i-n structure is formed with the interface layer at the p/i interface. Optionally, an additional interface layer treated with a hydrogen-containing plasma is formed between the intrinsic layer and the n-doped layer. Alternatively, a hydrogen-containing plasma is used to treat an upper portion of the intrinsic layer prior to deposition of the n-doped semiconductor layer. The interface layer is also applicable to-multi-junction solar cells with plural p-i-n structures. The p-doped and n-doped layers can optionally include sublayers of different compositions and different morphologies (e.g., microcrystalline or amorphous). The overall structure shows both an increased stability with respect to light-induced degradation and an improved performance level.

### CROSS-REFERENCE TO RELATED APPLICATIONS

This application claims priority to U.S. Provisional Patent Application No. 61/645,121 filed May 10, 2012, the disclosure of which is incorporated by reference herein.

### FIELD OF THE INVENTION

The invention relates to improved solar cells and, more particularly, to improved solar cells having enhanced resistance to light-induced degradation due to thin wide optical bandgap interface films positioned at one or more locations within the solar cell structure.

### BACKGROUND

In order to create high efficiency silicon-based thin film solar cells, high open circuit voltage (Voc), high current capacity, and long-term stability are highly desirable. In these solar cells, one or more p-i-n (or, alternatively, n-i-p) structures form the basis for converting photons from an incident light source into an electromotive force. However, long term stability is affected by persistent exposure to this incident light source. One consequence of this exposure is light-induced degradation of the solar cell. Degradation can be measured, for example, by the reduced fill factor, that is, the ratio of maximum obtainable power to the product of the open-circuit voltage and short-circuit current.

Attempts have been made to reduce solar cell light-induced degradation through the insertion of barrier layers to minimize dopant diffusion between doped and undoped layers of a p-i-n structure, particularly during device fabrication. U.S. Pat. No. 8,252,624 creates an amorphous silicon and carbon-containing barrier layer (a-SiC:H) between a p-doped silicon layer and an intrinsic silicon layer. In particular, materials with Si—C bonds are described as capturing boron atoms to prevent contamination of the adjacent intrinsic silicon layer. However despite the good performance of a-SiC:H buffers these layers suffer from light-induced degradation (Staebler-Wronski Effect, SWE). This is due to enhanced metastable defects induced by the incorporated carbon. The level of degradation/stability of the a-SiC:H layer is directly linked to the concentration of carbon.

Other alternatives have been proposed to increase V_{OC} while maintaining long-term stability. U.S. Patent Publication No. 2011/0308583 describes the formation of a nanocrystalline silicon-containing layer between an amorphous p-doped silicon layer and an intrinsic silicon layer. The layer can be formed through deposition of the nanocrystalline layer or through conversion of a portion of the amorphous p-doped silicon layer to a nanocrystalline material. Although the published application describes the effect on V_{OC} of the various layers, it fails to address the issue of long-term stability/light-induced degradation.

In a thesis by R. Platz, the mechanism of enhanced V_{OC} with barrier layers “is that the band-offset at the conduction band edge between the wide gap buffer layer and the intrinsic layer (i layer) prevents electrons from diffusing back to the p-layer and recombining instead of drifting to the n-layer.” The Platz thesis suggests the use of thin amorphous silicon layers (a-Si:H) deposited under high hydrogen dilution conditions between the p-doped and intrinsic layers to enhance V_{OC} of the final device. However, hydrogenated amorphous silicon also suffers from light-induced degradation (SWE) and the suggested amorphous silicon layer will not increase performance over a solar cell's lifetime.

Thus there is a need in the art for improved materials that resist light-induced degradation, thus ensuring improved solar cell performance.

### SUMMARY OF THE INVENTION

The present invention provides solar devices with greater resistance to light-induced degradation, ensuring an improved performance level. The invention provides a novel wide optical bandgap interface film with improved resistance to light-induced degradation through treatment with a hydrogen-containing plasma.

In one embodiment, a method of making solar cells with improved resistance to light-induced degradation is described. One or more p-doped semiconductor layers are deposited over a transparent substrate and electrode. The p-doped layer is comprised of least one sub-layer comprising p-doped amorphous silicon, p-doped amorphous silicon-carbon, p-doped amorphous silicon-oxygen, p-doped microcrystalline silicon, p-doped microcrystalline hydrogenated silicon, p-doped microcrystalline silicon-carbon, or p-doped microcrystalline silicon-oxygen.

Over the p-doped layer, a wide optical bandgap interface film is formed. This wide optical bandgap layer consists essentially of intrinsic hydrogenated amorphous silicon film. This film is treated with a hydrogen plasma, producing a light-degradation resistant film.

An intrinsic semiconductor layer including silicon is deposited over the wide optical bandgap interface film. One or more n-doped semiconductor layers is deposited over the intrinsic semiconductor layer. The n-doped layer is comprised of at least one sub-layer including n-doped amorphous silicon, n-doped amorphous silicon-carbon, n-doped amorphous silicon-oxygen, n-doped microcrystalline silicon, n-doped microcrystalline hydrogenated silicon, n-doped microcrystalline silicon-carbon, or n-doped microcrystalline silicon-oxygen.

At least a further electrode layer is formed over the n-doped layer.

The invention finds further application in tandem or multi junction solar cells with plural p-i-n structures, some of which are amorphous semiconductor-based and others which are microcrystalline semiconductor-based.

### BRIEF DESCRIPTION OF THE DRAWINGS

FIG. 1 schematically depicts a cross-sectional view of an amorphous silicon-based solar cell according to one embodiment of the present invention.

FIG. 2 schematically depicts a cross-sectional view of a tandem solar cell with multiple p-i-n structures according to a further embodiment of the present invention.

FIG. 3 is a graph of optical bandgaps for amorphous silicon, amorphous silicon treated with hydrogen, and amorphous silicon-carbon alloys.

FIG. 4 depicts the absorption coefficient vs. bandgap energy for a hydrogen treated wide optical bandgap material and an untreated wide optical bandgap material.

### DETAILED DESCRIPTION

### Definitions

Processing in the sense of this invention includes any chemical, physical or mechanical effect acting on substrates.
Substrates in the sense of this invention are components, parts or workpieces to be treated in a processing apparatus. Substrates include but are not limited to flat, plate shaped parts having rectangular, square or circular shape. In a preferred embodiment this invention addresses essentially planar substrates of a size >1 m², such as thin glass plates.
A vacuum processing or vacuum treatment system or apparatus comprises at least an enclosure for substrates to be treated under pressures lower than ambient atmospheric pressure. CVD Chemical Vapor Deposition is a well-known technology allowing the deposition of layers on heated substrates. A usually liquid or gaseous precursor material is being fed to a process system where a thermal reaction of said precursor results in deposition of said layer.
TCO stands for transparent conductive oxide, TCO layers consequently are transparent conductive layers.
The terms layer, coating, deposit and film are interchangeably used in this disclosure for a film deposited in vacuum processing equipment, be it CVD, LPCVD, plasma enhanced CVD (PECVD) or PVD (physical vapor deposition).
A solar cell or photovoltaic cell (PV cell) is an electrical component, capable of transforming light (essentially sun light) directly into electrical energy by means of the photoelectric effect. A thin-film solar cell in a generic sense includes, on a supporting substrate, at least one p-i-n junction established by a thin film deposition of semiconductor compounds, sandwiched between two electrodes or electrode layers. A p-i-n junction or thin-film photoelectric conversion unit includes an intrinsic semiconductor compound layer sandwiched between a p-doped and an n-doped semiconductor compound layer. The term thin-film indicates that the layers mentioned are being deposited as thin layers or films by processes such as PEVCD, CVD, PVD, or sputtering. Thin layers essentially mean layers with a thickness of 10 μm or less.
Optical bandgap: An optical bandgap (E_Tauc) is a bandgap measured using optical transmission and reflection, that is, a Tauc plot. The optical bandgap is typically expressed in electron volts with the notation Tauc indicating that it has been measured by optical techniques.
A wide optical bandgap interface material according to the invention is a semiconductor layer having an optical bandgap greater than the optical bandgap of an intrinsic amorphous semiconductor layer in the same solar cell device. For an amorphous silicon interface material treated by hydrogen plasma of the present invention, the wide optical bandgap (E_Tauc) is greater than about 1.75 eV and, more particularly, greater than about 1.78 eV. Note that intrinsic amorphous silicon for solar cells of the present invention has an optical bandgap (E_Tauc) on the order of 1.7 eV while intrinsic crystalline silicon has an optical bandgap (E_Tauc) on the order of 1.1 eV.

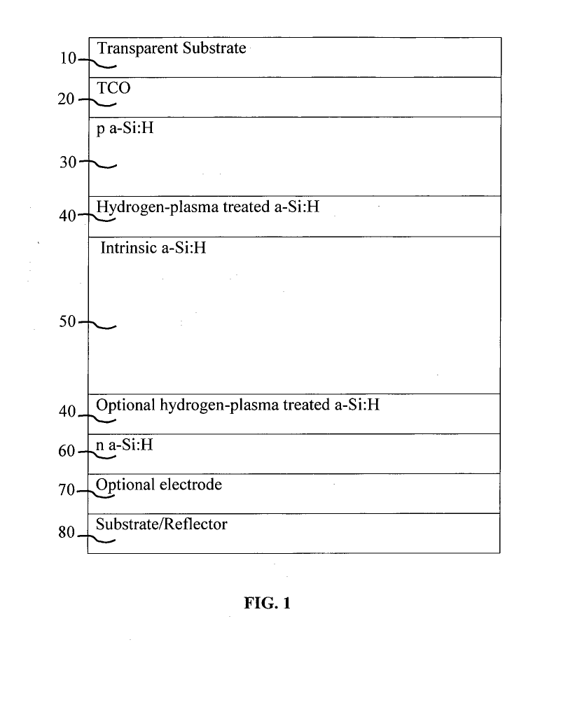

Turning to the drawings in detail, FIG. 1 shows a cross-sectional view of a solar cell 100 according to the present invention. A transparent substrate 10 with a TCO electrode layer 20 is provided or formed in a vacuum processing system. Typically the TCO electrode layer includes SnO₂ and/or ZnO or another known transparent conductive oxide such as indium tin oxide.

A p-doped semiconductor layer 30 is deposited over the TCO electrode layer 20 typically by a type of chemical vapor deposition such as plasma-enhanced chemical vapor deposition. As used herein, the term “over” when referring to a second layer as positioned “over” a first layer includes both the situation in which the first and second layers are in direct contact and the situation in which one or more intermediate layers are positioned between the first and second layers. Further, although FIG. 1 shows a p-i-n structure in which the p-doped layer is first deposited, the invention is equally applicable to n-i-p structures in which the n-doped layer is first deposited, typically on an opaque substrate.

In an exemplary embodiment, at least a portion of the p-doped semiconductor layer 30 is an amorphous layer including silicon. However, other silicon-including semiconductor layers can also be used in p-doped semiconductor layer 30. These include, but are not limited to, p-doped silicon-germanium alloys, amorphous Si:C, amorphous SiOx, silicon-germanium-carbon alloys, and other known silicon-based materials used in solar cell applications. The p-dopant is typically boron although other dopants can be selected based on the desired electrical properties of the layer.

The p-doped layer need not be a single composition or a single morphology. That is, p-doped semiconductor layer may comprise one or more sublayers of different compositions and morphologies. In particular, a first sublayer including p-doped microcrystalline silicon (μc-Si) or microcrystalline hydrogenated silicon (μc-Si:H) or other p-doped microcrystalline layers that include silicon can be deposited followed by one or more p-doped layers that include amorphous silicon (including amorphous Si:C, amorphous SiOx, silicon-germanium-carbon alloys, etc. as discussed above).

A wide optical bandgap interface film 40 is deposited over p-doped semiconductor layer 30. Interface film is formed from a thin layer of intrinsic hydrogenated amorphous silicon, on the order of 5 to 20 nanometers. Plasma-enhanced chemical vapor deposition from a silicon-containing precursor case such as a silane and hydrogen can be used to form the wide optical bandgap interface film. Using plasma-enhanced chemical vapor deposition is advantageous in that the deposition conditions can be controlled to select a level of hydrogenation and thus select the optical properties of the film. Note that carbon is not included in the wide optical bandgap interface film 40 due to its demonstrated light-induced degradation effects. Other materials besides amorphous silicon that do not substantially affect the optical and barrier properties of the wide optical bandgap interface film 40 may optionally be included. In particular, the material can be optionally slightly doped with boron without affecting its overall properties. The addition of oxygen is also contemplated as such films are more resistant to light-based degradation and also exhibit wide optical bandgaps. In particular, the deposition of the wide optical bandgap interface film is performed without the use of any carbon-containing gas such as CH₄ or other hydrocarbon gases. Consequently, wide optical bandgap interface film 40 is essentially free of carbon. As used herein, the term “essentially free of carbon” means that the level of carbon is below any level that could affect the optical or electrical properties of the layer.

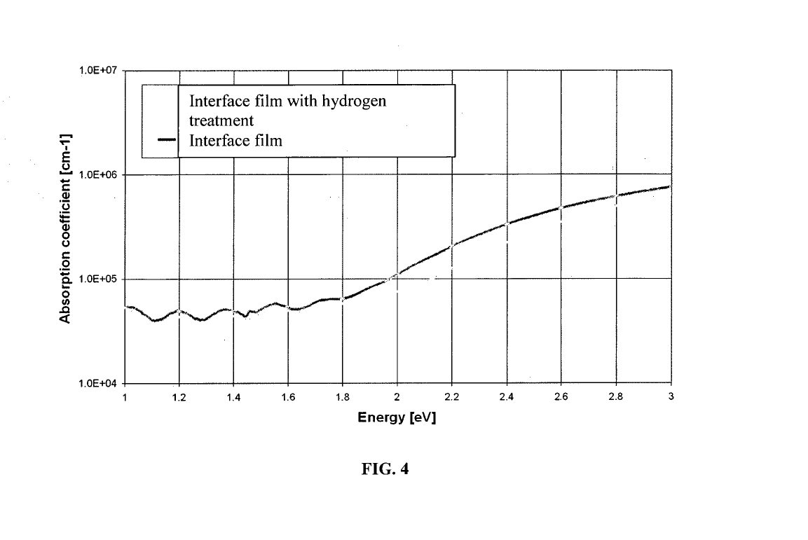

In order to substantially increase the resistance of wide optical bandgap interface film 40 to light-induced degradation, a hydrogen-containing plasma treatment is performed on the deposited film. The treatment is typically performed for a period of approximately 120 second to 600 seconds. Without being limited by theory, it is postulated that the wide bandgap a-Si:H shows principally fewer defects (as compared to layers that include carbon) and an improved stability with respect to SWE and that the hydrogen plasma treatment modifies the bandgap of the layer. In visual studies of the layer, the hydrogen plasma treatment brightens the color of the layer as can be seen in FIG. 4 which depicts the absorption coefficient vs. bandgap energy for a hydrogen treated wide optical bandgap material and an untreated wide optical bandgap material.

An intrinsic layer of amorphous semiconductor material 50 is deposited over the wide optical bandgap interface film 40. As with p-doped semiconductor layer 30, intrinsic layer 50 can be silicon based and deposited through chemical vapor deposition or plasma-enhanced chemical vapor deposition. Optionally a further layer of wide optical bandgap interface film 40 with plasma treatment can be formed over the intrinsic layer 50. Alternatively, the upper surface of intrinsic layer 50 can be treated with the hydrogen plasma treatment described above. In some embodiments it may be advantageous to insert plural wide optical bandgap interface films 40 within the intrinsic layer 50 to improve resistance to light degradation of the overall device.

Over the intrinsic layer 50 (and optional additional interface layer) is formed an n-doped semiconductor layer 60. As with the p-doped layer, the n-doped layer can comprise one or more sublayers of different compositions and/or morphologies. In particular, a first sublayer including n-doped amorphous silicon, n-doped amorphous Si:C, n-doped amorphous SiOx, n-doped silicon-germanium-carbon alloys or other n-doped layer including amorphous silicon can be formed. Over this first sublayer is optionally deposited n-doped microcrystalline silicon (μc-Si) or n-doped microcrystalline hydrogenated silicon (μc-Si:H) or another n-doped microcrystalline layer(s) that includes silicon. Phosphorus is typically selected as the n-dopant although other doping materials can be selected based on desired electrical properties.

Over the n-doped layer an electrode layer 70 and reflective substrate electrode 80 are formed or bonded thereto.

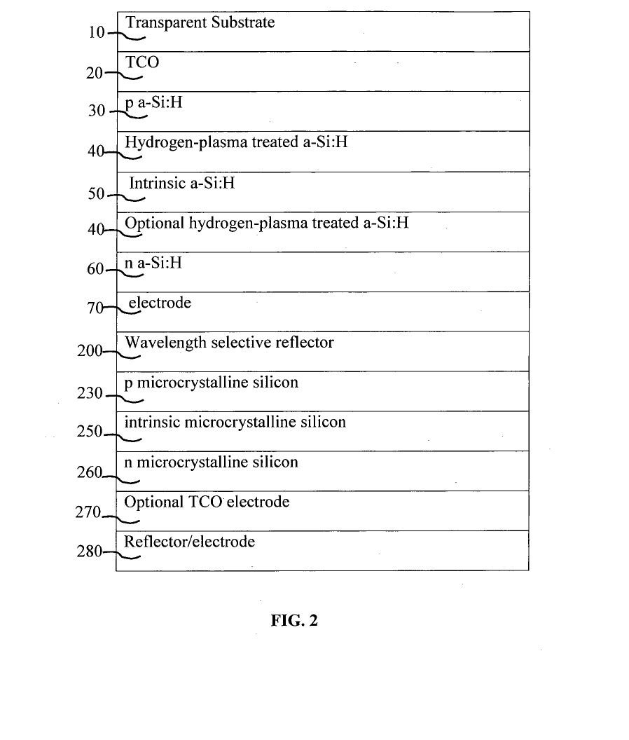

FIG. 2 depicts a tandem solar cell structure with two p-i-n structures. The top p-i-n structure is substantially similar to the device described in FIG. 1. A wavelength selective reflector 200 is positioned between the first and second p-i-n structures to selectively reflect a portion of the incident light back into the amorphous p-i-n structure. Note that selection of the portion of incident light that is reflected back into the first p-i-n structure will be impacted by the increased stability imparted by the interface layer(s) 40. If the amorphous p-i-n structure has an improved light-induced stability, then together with the thickness of wavelength selective reflector 200 the tandem device can be adapted for further enhancing the stabilized efficiency.

In the second p-i-n structure, layers 230, 250, and 260 are respective p-doped, intrinsic, and n-doped microcrystalline silicon deposited by plasma-enhanced CVD.

Electrode layer 270 and reflector/reflective electrode 280 are provided for the second p-i-n structure. Note that the structure of FIG. 2 is sometimes called a “micromorph” structure since it incorporates both a microcrystalline silicon-based p-i-n and an amorphous silicon-based p-i-n. Since microcrystalline silicon and amorphous silicon absorb different regions of an incident light spectrum, having tandem p-i-n structures increases the overall efficiency of the device by using a greater portion of the available light spectrum.

Of course it is understood that the novel wide optical bandgap interface film can be used in a wide variety of solar cells including a wide variety of layer configurations and the above devices are merely exemplary configurations rather than limiting embodiments. Such solar cells include multiple junction solar cells, tandem cells, single junction cells of various layer thicknesses and morphologies.

### EXAMPLES

### 1. Measurement of Optical Bandgap

In order to characterize to characterize the inventive interface films of the present invention, stacks of 6 multi-layers of thin ˜12 nm interface films were prepared. The hydrogen plasma was applied after deposition of each of the 12 nm thick films in the multilayer. The multilayer of ˜70 nm is more suitable for reliable characterization than an individual thin 15-20 nm single layer.

The following process conditions for layers were investigated:
CH₄=50→a-SiC:H layer with CH₄, no H₂ plasma after deposition
CH₄=0→a-Si:H layer without CH₄, no H₂-plasma after deposition
H₂.v1→a-Si:H layer without CH₄, with 100 sec H₂-plasma at 0.8 mbar
H₂.v2→a-Si:H layer without CH₄, with 100 sec H₂-plasma at 2.5 mbar

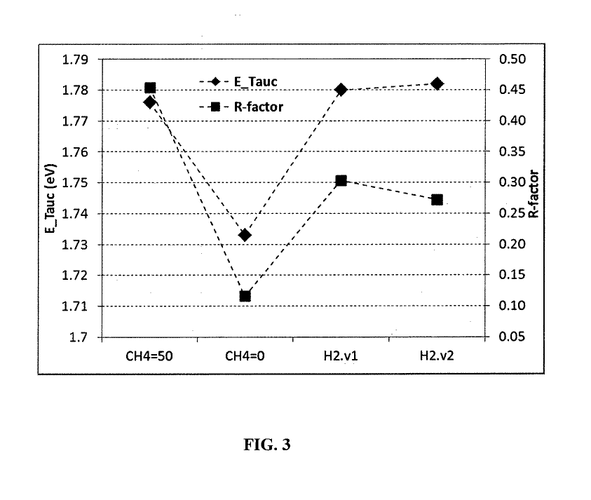

The results are shown in the FIG. 3 which depicts the optical bandgap as a function of the various compositions and processing conditions. As compared to the a-SiC:H layer, the layer without CH₄ has a lower optical bandgap energy (lower E_Tauc) but very good material quality (low R-factor). Upon application of a hydrogen plasma after deposition, the band gap energy E_Tauc increases to values similar to those obtained for the layer with CH₄. At the same time, the layer quality deteriorates (i.e., R-factor increases) as compared to the layer without CH₄ but it is still significantly better as compared to the layer with CH₄ (e.g., for H₂.v2).

### 2. Measurement of Device Characteristic Using the Wide Optical Bandgap Film

### a. Single p-i-n Structure

In Table 1 the inventive wide optical bandgap interface film fabrication parameters (typical gas flows, thickness, pressure, power densities, H₂ plasma treatment) are summarized. The vacuum system is a PECVD R&D KAI M reactor. The interface film is compared to a barrier layer of amorphous silicon/carbon (a-SiC:H) deposited by plasma enhanced chemical vapor deposition.

TABLE 1
Typical fabrication parameters of layers in a 40.68 MHz PECVD reactor with
substrate size of ~3000 cm².

| | | | | | Thickness | | Power |
|---|---|---|---|---|---|---|---|
| | Temp. | CH₄ | SiH₄ | H₂ | [nm] or | Pressure | density |
| Layers | [° C.] | [sccm] | [sccm] | [sccm] | Time [s] | [mbar] | [mW/cm²] |
| a-SiC:H | 160-200 | 10-20 | 40 | 0-800 | 5 to 20 nm | 0.5 | 23 |
| a-Si:H | 160-200 | 0 | 40 | 100-800 | 5 to 20 nm | 0.5 | 23 |
| wide gap | | | | | | | |
| interface | | | | | | | |
| film | | | | | | | |
| Hydrogen | 160-200 | — | — | 400-500 | 120 to 600 s | 0.8-1.5 | 40-50 |
| plasma | | | | | | | |

The beneficial effect on the fill factor and various other solar cell parameters by using the inventive wide optical bandgap materials is illustrated in Table 2 (Series 1 and Series 2) for a-Si:H single junction solar cell in the initial state and after light induced degradation.

TABLE 2
a-Si:H with hydrogen plasma interface film vs. a-SiC:H interface film in a-Si:H
single junction p-i-n (Series 1 and Series 2)

| | | | | | | |
|---|---|---|---|---|---|---|
| | | | | | | Degradation |
| State | Interface film | J_{sc} [mA/cm²] | V_{oc} [mV] | FF [%] | η [%] | [%] |

Series 1

| | | | | | | |
|---|---|---|---|---|---|---|
| Initial | a-SiC:H | 17.4 | 902 | 70.2 | 11.0 | / |
| | a-Si:H + H₂ plasma | 17.7 | 900 | 70.5 | 11.2 | / |
| 300 h | a-SiC:H | 16.7 | 879 | 61.0 | 8.9 | 19.1 |
| | a-Si:H + H₂ plasma | 16.8 | 879 | 62.9 | 9.3 | 17.0 |

Series 2

| | | | | | | |
|---|---|---|---|---|---|---|
| Initial | a-SiC:H | 17.3 | 903 | 71.9 | 11.2 | / |
| | a-Si:H + H₂ plasma | 17.5 | 900 | 71.4 | 11.3 | / |
| 300 h | a-SiC:H | 16.4 | 880 | 62.0 | 8.9 | 20.5 |
| | a-Si:H + H₂ plasma | 16.6 | 881 | 63.5 | 9.3 | 17.7 |

### b. Multiple p-i-n Structure

For tandem junction solar cells the parameters presented in Table 3 correspond to the following tandem structure:
a-Si:H p-i-n structure: 250 nm
wavelength selective mirror: 70 nm
microcrystalline Si:H p-i-n: 2000 nm

The tandem junction solar cells are deposited on LPCVD ZnO (˜1200 nm) on textured Corning glass and are bottom limited. A silicon/carbon layer is compared to the inventive hydrogen plasma treated interface layer positioned between the p/i interface and the i/n interface. The two solar cells are each deposited, manipulated, measured and degraded in the same manner

Table 3 shows these parameters for use of the inventive film for tandem amorphous/microcrystalline solar cells. Both cells clearly show that degraded fill factor values are better for the novel wide optical bandgap interface film incorporated in the solar cells (wide gap a-Si:H and exposed to hydrogen plasma). As Voc and Jsc are of same quality the inventive film yields to improved stability of solar cell efficiencies.

TABLE 3
a-Si:H with hydrogen plasma interface film vs. a-SiC:H interface film in a tandem
junction p-i-n solar cell (Series 1)
Series 1

| | | | | | | Degradation |
|---|---|---|---|---|---|---|
| State | Interface film | J_{sc} [mA/cm²] | V_{oc} [mV] | FF [%] | η [%] | [%] |
| Initial | a-SiC:H | 12.7 | 1380 | 73.5 | 12.9 | / |
| | a-Si:H + H₂ plasma | 12.6 | 1375 | 74.2 | 12.9 | / |
| 300 h | a-SiC:H | 12.4 | 1353 | 67.3 | 11.3 | 12.4 |
| | a-Si:H + H₂ plasma | 12.3 | 1356 | 69.5 | 11.6 | 10.1 |
| 1000 h | a-SiC:H | 12.4 | 1349 | 64.7 | 10.9 | 15.5 |
| | a-Si:H + H₂ plasma | 12.3 | 1361 | 68.5 | 11.5 | 10.9 |

### 3. Variations in Process Parameters for Forming Wide Optical Bandgap Film

Various PECVD process parameters for fabricating the wide optical bandgap interface film are given in Table 4. The applied RF power varied from 250-600 Watts while the pressure was also varied from 0.5 to 4.0 mbar. Performing the H2-plasma treatment at higher process pressure (i.e. 2.5 mbar instead of 0.8 mbar) or for shorter treatment time (50 sec instead of 100 sec) leads to improved material quality and to similar or lower band gap energy as compare to a reference layer. A reduction in the RF power during preparation of buffer layer results in significantly improved material quality at the same band gap energy. Also combinations of lower RF power during buffer layer deposition and H2-plasma at higher process pressure lead to good single layer results.

TABLE 4
Process parameters for forming a wide optical bandgap interface film

| | | | Pressure | RF Power | Time |
|---|---|---|---|---|---|
| Sample ID | SiH4 (sccm) | H2 (sccm) | (mbar) | (W) | (sec) |
| X_SO3751_3 | 200 | 2000 | 0.5 | 350 | |
| | & H2-plasma | 2000 | 0.8 | 600 | 100 |
| X_SO3762_2 | 200 | 2000 | 0.5 | 350 | |
| | & H2-plasma | 2000 | 2.5 | 600 | 100 |
| X_SO3762_3 | 200 | 2000 | 0.5 | 250 | |
| | & H2-plasma | 2000 | 2.5 | 600 | 100 |
| X_SO3762_6 | 200 | 2000 | 0.5 | 350 | |
| | & H2-plasma | 2000 | 2.5 | 600 | 50 |
| X_SO3762_8 | 200 | 2000 | 0.5 | 250 | |
| | | 2000 | 4.0 | 600 | 100 |

While the foregoing invention has been described with respect to various embodiments, such embodiments are not limiting. Numerous variations and modifications would be understood by those of ordinary skill in the art. Such variations and modifications are considered to be included within the scope of the following claims.

What is claimed is:

1. A method for forming solar cells with improved resistance to light-induced degradation, the method comprising:
providing a transparent substrate having a transparent conductive first electrode layer formed thereon;
depositing one or more p-doped semiconductor layers over the transparent substrate and electrode, the one or more p-doped layers including at least one sub-layer including p-doped amorphous silicon, p-doped amorphous silicon-carbon, p-doped amorphous silicon-oxygen, p-doped microcrystalline silicon, p-doped microcrystalline hydrogenated silicon, p-doped microcrystalline silicon-carbon, or p-doped microcrystalline silicon-oxygen;
depositing a wide optical bandgap interface film consisting essentially of intrinsic hydrogenated amorphous silicon film on the p-doped semiconductor layer;
treating the wide optical bandgap interface film with a hydrogen plasma;
depositing an intrinsic semiconductor layer comprising silicon over the wide optical bandgap interface film;
depositing one or more n-doped semiconductor layers over the intrinsic semiconductor layer, the one or more n-doped semiconductor layers including at least one sub-layer including n-doped amorphous silicon, n-doped amorphous silicon-carbon, n-doped amorphous silicon-oxygen, n-doped microcrystalline silicon, n-doped microcrystalline hydrogenated silicon, n-doped microcrystalline silicon-carbon, or n-doped microcrystalline silicon-oxygen;
forming a second electrode over the n-doped semiconductor layer.

2. A method for forming solar cells with improved resistance to light-induced degradation according to claim 1 further comprising depositing a second wide optical bandgap interface film consisting essentially of intrinsic amorphous silicon film on the intrinsic semiconductor layer; and
treating the second wide optical bandgap interface film with a hydrogen plasma.

3. A method for forming solar cells with improved resistance to light-induced degradation according to claim 1 further comprising treating the deposited intrinsic semiconductor layer with a hydrogen plasma prior to depositing the n-doped semiconductor layer.

4. A method for forming solar cells with improved resistance to light-induced degradation according to claim 1 further comprising:
forming a wavelength selective reflector over the n-doped semiconductor layer;
forming a p-i-n semiconductor structure over the wavelength selective reflector;
forming the second electrode over the p-i-n semiconductor structure.

5. A method for forming solar cells with improved resistance to light-induced degradation according to claim 4 wherein forming the p-i-n semiconductor structure comprises:
forming a p-doped microcrystalline semiconductor layer comprising microcrystalline silicon;
forming an intrinsic microcrystalline semiconductor layer comprising microcrystalline silicon over the p-doped microcrystalline semiconductor layer;
forming an n-doped microcrystalline semiconductor layer comprising microcrystalline silicon over the intrinsic microcrystalline semiconductor layer.

6. A solar cell with improved resistance to light-induced degradation formed according to claim 1.

7. A solar cell with improved resistance to light-induced degradation formed according to claim 1 wherein the wide optical bandgap interface film is essentially free of carbon.

8. A solar cell with improved resistance to light-induced degradation formed according to claim 4.

9. A solar cell with improved resistance to light-induced degradation formed according to claim 5.

10. A method for forming solar cells with improved resistance to light-induced degradation according to claim 5 further comprising depositing a wide optical bandgap interface film consisting essentially of intrinsic amorphous silicon film on the p-doped microcrystalline layer;
treating the wide optical bandgap interface film deposited on the p-doped microcrystalline layer with a hydrogen plasma.

11. A solar cell with improved resistance to light-induced degradation formed according to claim 10.

12. In a silicon-based solar cell having at least one p-i-n structure, a portion of which includes amorphous silicon, the improvement comprising a wide optical bandgap interface film consisting essentially of hydrogen-plasma treated amorphous silicon with an optical Tauc bandgap of 1.75 eV or greater.

13. The silicon-based solar cell of claim 12 wherein the wide optical bandgap interface film is essentially free of carbon.

14. A method according to claim 1 wherein the treatment using the hydrogen plasma is performed for a time sufficient to produce an optical Tauc bandgap of 1.75 eV or greater.

15. A method according to claim 1 wherein the depositing of the wide optical bandgap interface film is performed without the use of any carbon-containing gas.

16. A method according to claim 1 wherein the p-doped semiconductor layer includes a p-doped microcrystalline silicon sub-layer and a p-doped amorphous silicon sublayer.

17. A method according to claim 1 wherein the n-doped semiconductor layer includes an n-doped microcrystalline silicon sub-layer and an n-doped amorphous silicon sublayer.

18. A method according to claim 1 further comprising depositing a wide optical bandgap interface film within the intrinsic semiconductor layer.
